(19) United States
(12) Patent Application Publication
(10) Pub. No.: US 2026/0086112 A1
(43) Pub. Date: Mar. 26, 2026

(54) TEST SYSTEM WITH IMPROVED CONTACT BLADE DESIGN AND METHODS OF USING THE SAME

(71) Applicant: Taiwan Semiconductor Manufacturing Company Limited, Hsinchu (TW)

(72) Inventors: Fang Chou Li, Hsinchu City (TW); Shu-Jung Tseng, Wuci Township (TW); Hui-Chang Yu, Hsinchu (TW)

(21) Appl. No.: 18/894,342

(22) Filed: Sep. 24, 2024

(51) Int. Cl. G01R 1/04; G01R 31/28

(52) U.S. Cl. CPC G01R 1/0466; G01R 31/2887; G01R 31/2896

(57) ABSTRACT

Test systems and methods testing semiconductor package structures including an improved contact blade design that provides improved testing reliability and minimizes damage to the package structure. The contact blade includes a “die pusher” having a lower surface that contacts an upper surface of the package structure in a region including one or more dies and an encapsulant material. The lower surface of the die pusher includes a non-planar contoured shape, such as a convex or concave shape, that is complementary to the non-planar shape of the upper surface of the package substrate. The lower surface of the die pusher includes a trench that corresponds to the location of a gap between adjacent dies of the package structure when the die pusher contacts the upper surface of the package structure. The contact blade may apply pressure more evenly to the package structure to improve test reliability while minimizing damage.

### BACKGROUND

The semiconductor industry has continually grown due to continuous improvements in integration density of various electronic components, e.g., transistors, diodes, resistors, capacitors, etc. For the most part, these improvements in integration density have come from successive reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of an in-progress multi-chip module (MCM) package according to various embodiments of the present disclosure.

FIG. 1B is a vertical cross-section view of the in-progress MCM package taken along line A-A′ in FIG. 1A.

FIG. 2A is a vertical cross-section view of a test system for testing semiconductor package structures according to various embodiments of the present disclosure.

FIG. 2B is a vertical cross-section view of an in-progress MCM package disposed in the test system of FIG. 2A according to various embodiments of the present disclosure.

FIG. 2C is a vertical cross-section view of an in-progress MCM package undergoing a testing process by the test system of FIG. 2A according to various embodiments of the present disclosure.

FIG. 3A is a vertical cross-section view of a die pusher according to various embodiments of the present disclosure.

FIG. 3B is a bottom view of the die pusher shown in FIG. 3A.

FIG. 4 is a vertical cross-section view of a die pusher according to another embodiment of the present disclosure.

FIG. 5A is a top view of an in-progress multi-chip module (MCM) package according to an alternative embodiment of the present disclosure.

FIG. 5B is a bottom view of an alternative die pusher shown used in conjunction with the alternative MCM package of FIG. 5A.

FIG. 6 is a flow chart showing a method of testing an in-progress MCM package according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to test systems used for testing of semiconductor package structures and methods therefor. In particular, various embodiment include test systems having an improved contact blade design that enables more reliable testing of, and minimizes damage to, semiconductor package structures.

A semiconductor package often includes multiple semiconductor integrated circuit (IC) devices, which may also be referred to as “chips” or “dies,” mounted to a single support, or “package substrate.” A semiconductor package that includes multiple dies on a package substrate may be referred to as a “multi-chip module” (MCM) package. The assembly process for fabricating an MCM package is typically a multi-step process that may include, for example, placing dies on a front side of a package substrate, performing a bonding process to mechanically and electrically couple the dies to the package substrate, performing an encapsulation process that may include providing a molding compound or other suitable protective material around and between the dies, and optionally providing other components, such as a lid, a heat spreader, etc., over the dies and the molding compound. In some cases, bonding features, such as a ball grid array (BGA) may be provided on the back side of the package substrate to enable the MCM package to be bonded to another structure, such as a printed circuit board (PCB).

In some cases, the assembly process for an MCM package may occur in multiple stages. For example, dies of a first type (e.g., logic dies, such as CPU die(s), GPU die(s), ASIC die(s), etc.) may be mounted to the package substrate and encapsulated using a suitable encapsulant material. Subsequently, one or more additional dies of a second type (e.g., one or more memory dies, such as SRAM die(s), HBM die(s), etc.), may be mounted to the package substrate. Other components, such as a lid, heat spreader and/or bonding features may then be provided.

It may be advantageous to perform testing of the MCM package at various stages of the assembly process. A specialized test system (which may also be referred to as a “tester”) may be used to test and validate the designed functionality of the MCM package and the components thereof. The testing process may include placing partially- and/or fully-assembled MCM packages into a socket of the test system that includes a plurality of contact pins extending into a socket housing. Each of the contact pins may be connected to a circuit board (which may also be referred to as a “load board”) on which the socket is supported. The test system may also include a contact blade that may be configured to apply a controlled pressure to the upper surface of the MCM package to secure engagement between electrical contacts (e.g., bonding pads, solder balls, etc.) located on the underside of the MCM package and respective contact pins within the socket housing. The test system may be configured to transmit electrical test signals to the MCM package through the load board and the contact pins and to detect electrical response signals from the MCM package that are received through the contact pins and the load board. The detected response signals from the MCM package may be analyzed and used to determine whether the MCM package includes any functional defects.

Performing an above-described test multiple times during the assembly of an MCM package may enable the identification of faulty or defective devices at a relatively early stage of the assembly process, which may result in enhanced cost savings. For example, an initial test may be performed after dies of a first type (e.g., logic dies) are mounted to the package substrate and encapsulated, and a second test may be performed after final assembly is completed.

However, current testers are often not well-suited for testing partially-assembled (i.e., “in-progress”) MCM packages. In particular, in-progress MCM packages are often subject to a high degree of warpage (e.g., >400 μm at room temperature) that may result due to the in-progress MCM package having a curved (e.g., convex or concave) shape. This curved shape may lead to poor contact between the electrical contacts on the underside of the in-progress MCM package and the contact pins of the tester. In addition, the pressure applied to the non-planar upper surface of in-progress MCM package by the contact blade of the tester may cause damage to the in-progress MCM package, including cracking of the dies, which may result in poor device performance and reduced yields.

Accordingly, there is a desire for improvements in test systems used to test the functionality of in-progress MCM packages. Various embodiments of the present disclosure include test systems and methods testing semiconductor package structures, including MCM packages. Test systems according to various embodiments may include an improved contact blade design that provides improved testing reliability and minimizes damage to the devices being tested. In various embodiments, the contact blade of the test system may include a “die pusher” having a lower surface that is configured to contact and apply pressure against an upper surface of the in-progress MCM package during the test process. The lower surface of the die pusher may contact the in-progress MCM package in a region of the in-progress MCM package including one or more dies and optionally an encapsulant material surrounding the one or more dies. The lower surface of the die pusher may have a non-planar contoured shape, such as a convex or concave shape, that may be complementary to the non-planar shape of the upper surface of the in-progress MCM package that is contacted by the die pusher. Accordingly, the shape of the lower surface of the die pusher may mimic or conform to the warpage characteristics of the in-progress MCM package, which may enable the contact blade to apply pressure more evenly to the in-progress MCM package which may help to mitigate against die cracking and improve test reliability.

In some embodiments, the die pusher may include at least one trench in the lower surface of the die pusher. The location of each trench may correspond to the location of a gap between adjacent dies mounted to the in-progress MCM package in instances in which the die pusher is brought into contact with the upper surface of the in-progress MCM package. This may further mitigate against the risk of the contact blade causing die cracking or other damage to the in-progress MCM package.

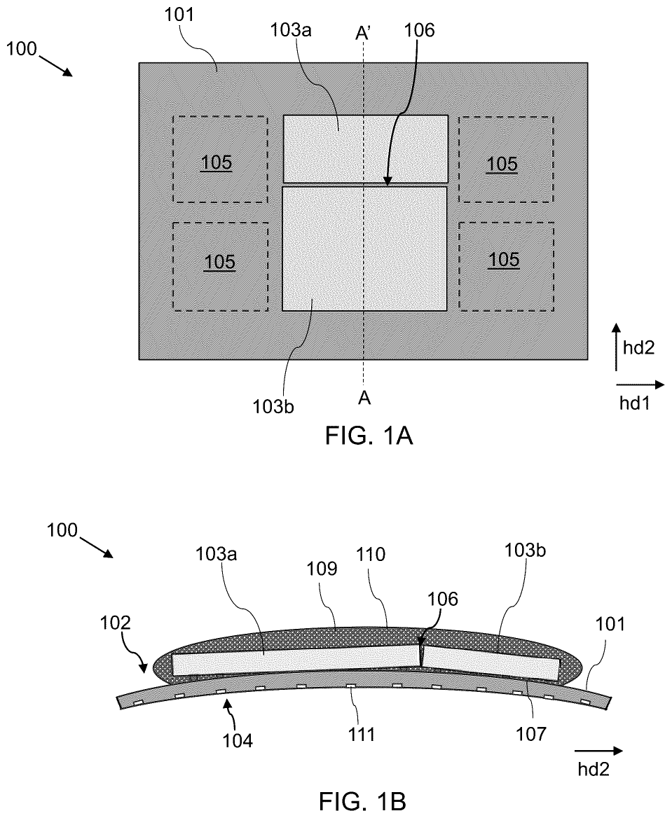

FIG. 1A is a top view of an in-progress multi-chip module (MCM) package 100 according to various embodiments of the present disclosure. FIG. 1B is a vertical cross-section view of the in-progress MCM package 100 taken along line A-A′ in FIG. 1A. Referring to FIGS. 1A and 1B, the in-progress MCM package 100 may include a substrate 101 having a first (i.e., upper) surface 102 and a second (i.e., bottom) surface 104. The package substrate 101 may include a suitable support element on which a plurality of semiconductor dies may be mounted. In various embodiments, the package substrate 101 may include a suitable dielectric material. In some embodiments, the dielectric material of the package substrate 101 may include an organic dielectric material. In one non-limiting embodiment, the package substrate 101 may include a solid substrate core composed of a sheet of laminate reinforced resin with layers of a polymer-based dielectric material, such as Ajinomoto Buildup Film (ABF)® product, located over the surfaces of the substrate core. Conductive interconnect features (e.g., metal lines, vias and/or bonding pads) may extend through the dielectric material(s) of the package substrate 101 between the first side 102 and the second side 104 of the package substrate 101. The conductive interconnect features may include a plurality of bonding pads 111 located on the second side 104 of the package substrate 101. An optional outer coating layer (e.g., a solder resist layer) may be located on the first side 102 and the second side 104 of the package substrate 101. Other suitable materials and/or configurations for the package substrate 101 are within the contemplated scope of disclosure.

Referring again to FIGS. 1A and 1B, a plurality of dies 103a and 103b may be mounted over the first side 102 of the package substrate 101. Although FIGS. 1A and 1B illustrate a first die 103a and a second die 103b mounted to the package substrate 101, it will be understood that a greater or lesser number of dies may be mounted to the package substrate 101. Each of the dies 103a and 103b may include any suitable die, such as a logic die (e.g., a CPU die, a GPU die, an ASIC die, etc.), a memory die (e.g., an SRAM die, an HBM die, etc.), an analog die, an RF die, an integrated passive device (IPD) die, a deep trench capacitor (DTC) die, a non-functional “dummy” die, etc., including various combinations thereof. The dies 103a and 103b may be bonded to the package substrate 101 via a plurality of bonding features 107 that may provide a physical and electrical connection between the dies 103a and 103b and the package substrate 101. The bonding features 107 may electrically connect the dies 103a and 103b to conductive interconnect features extending within the underlying package substrate 101. In some embodiments, an underfill material (not shown in FIGS. 1A and 1B) may be provided between the dies 103a and 103b and the first surface 102 of the package substrate 101 and may laterally surround the bonding features 107.

The plurality of dies 103a and 103b may be bonded to the package substrate 101 using any suitable bonding technique, such as a microbump bonding technique, a direct bond (e.g., a metal-to-metal and dielectric-to-dielectric) bonding technique, a flip chip bonding technique, etc., including various combinations thereof. In some embodiments, the plurality of dies 103a and 103b may be directly attached to the first side 102 of the package substrate 101. Alternatively, or in addition, one or more of the plurality of dies 103a and 103b may be attached to an intervening structure, such as an interposer, that may be mounted to the first side 102 of the package substrate 101. The interposer may electrically couple the plurality of dies 103a and 103b to the package substrate 101. Each of the plurality of dies 103a and 103b may be laterally spaced from one another such that there is a gap 106 located between adjacent ones of the plurality of dies 103a and 103b.

Referring to FIG. 1B, an encapsulant material 109 may surround the plurality of dies 103a and 103b mounted to the package substrate 101. For clarity of illustration, the encapsulant material 109 is omitted from the top view of the in-progress MCM package 100 shown in FIG. 1A. The encapsulant material 109 may contact lateral side surfaces and optionally the upper surfaces of the plurality of dies 103a and 103b and may fill the gaps 106 between adjacent ones of the plurality of dies 103a and 103b. In some embodiments, the encapsulant material 109 may include an epoxy material. For example, the encapsulant material 109 may include an epoxy mold compound (EMC) that may include epoxy resin, a hardener (i.e., a curing agent), silica or other filler material(s), and optionally additional additives. The EMC may be applied around and optionally over the plurality of dies 103a and 103b in liquid or solid form, and may be hardened (i.e., cured) to form an encapsulant material 109 having sufficient stiffness and mechanical strength. Other suitable materials for the encapsulant material 109, such as a molded underfill (MUF) material, may also be utilized.

The in-progress MCM package 100 shown in FIGS. 1A and 1B may be in a state of partial assembly. In various embodiments, the plurality of dies 103a and 103b that are mounted to the package substrate 101 and encapsulated by the encapsulant material 109 may be a first set of plurality of dies 103a and 103b. The package substrate 101 may include one or more additional mounting regions 105 (indicated by dashed lines in FIG. 1A) to which a second set of one or more dies may be subsequently mounted. In some embodiments, the first set of plurality of dies 103a and 103b may be dies of a first type, such as logic dies, and the second set of dies may be dies of a second type, such as memory dies.

In many cases, the processing steps utilized to form an in-progress MCM package 100 as shown in FIGS. 1A and 1B may induce warpage of the package substrate 101. This is illustrated in FIG. 1B, which shows the package substrate 101 having a non-planar curved shape that “bows” downwards towards the periphery of the package substrate 101. In other embodiments, the warpage of the package substrate 101 may cause the package substrate 101 to “bow” upwards towards the periphery of the package substrate 101. As a result of this warpage, the upper surface 110 of the in-progress MCM package 100 (which in the embodiment of FIG. 1B is defined by the upper surface of the encapsulant material 109) may not be flat and may instead have a curved or other non-planar shape. In contrast, a fully assembled MCM package 100 may often include a lid, a heat spreader and/or another component mounted to the package substrate 101 such that the upper surface of the MCM package 100 is typically a flat planar surface. In the embodiment of FIG. 1B, the non-planar upper surface 110 of the in-progress MCM package 100 includes a convex curved shape. In other embodiments, the upper surface 110 may have a concave curved shape. As discussed above, a curved shape of the in-progress MCM package 100 may make testing of the package difficult using current testing systems. In particular, the pressure applied by the contact blade of the testing system against the non-planar upper surface 110 of the in-progress MCM package 100 may cause damage to the package 100, such as cracking of the dies 103a and 103b, and may also result in poor contact between the bonding pads 111 on the underside of the in-progress MCM package and the contact pins of the test system.

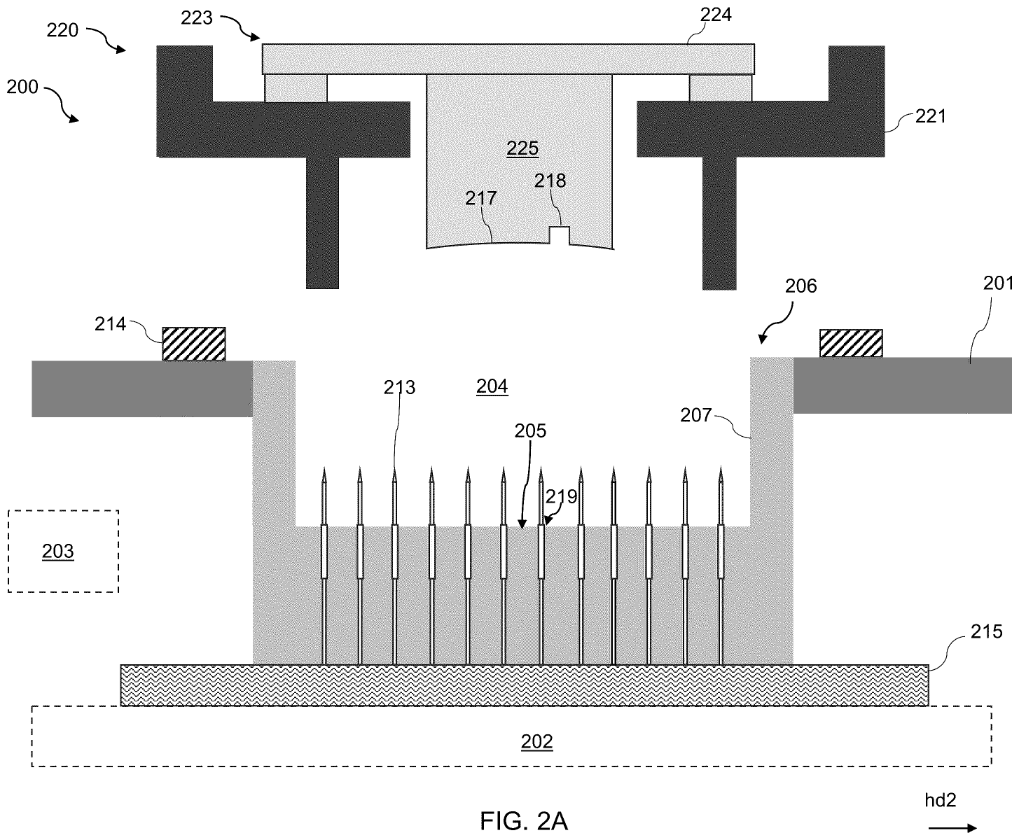

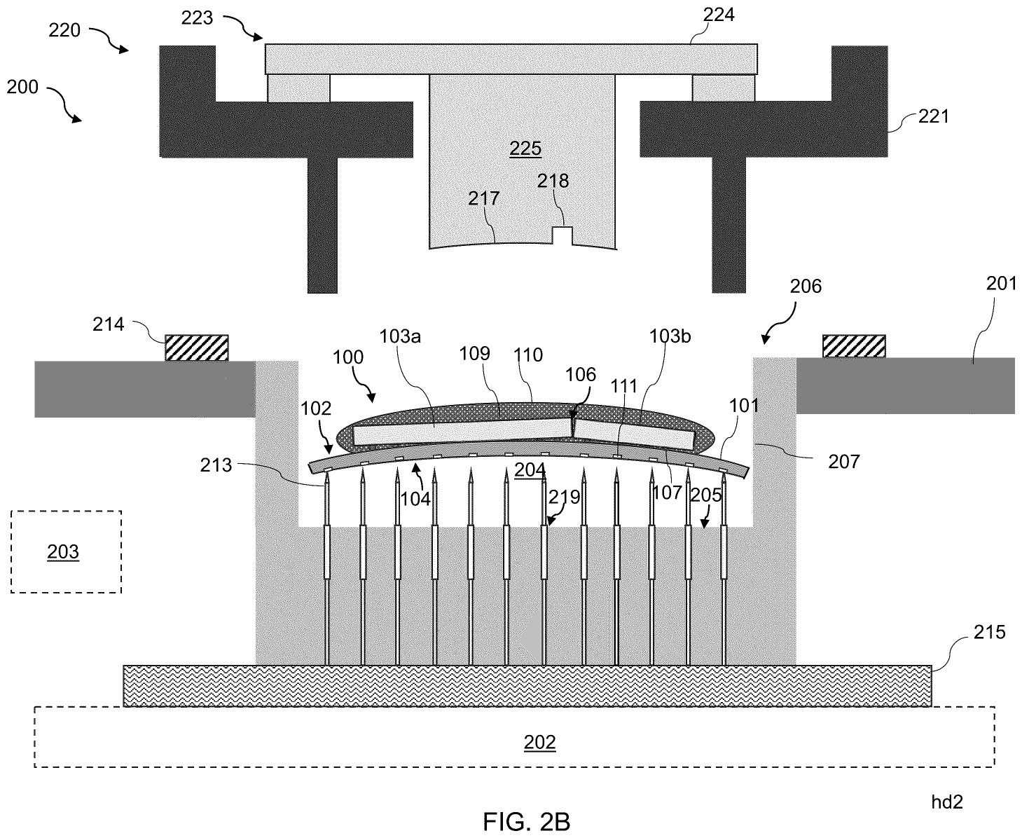

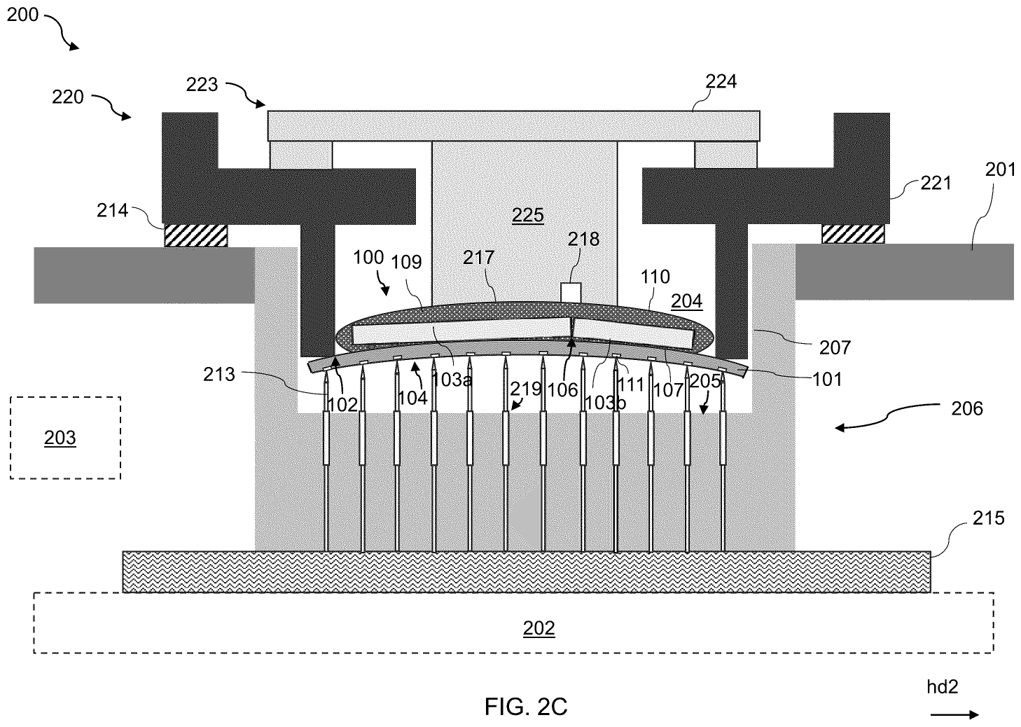

FIG. 2A is a vertical cross-section view of a test system 200 for testing semiconductor package structures according to various embodiments of the present disclosure. Referring to FIG. 2A, the test system 200 may include a controller 203 (e.g., a processor) that may control the operations of the test system 200 and a test head 202. In various embodiments, a socket 206 may be disposed on the test head 202. The socket 206 may be an electro-mechanical interface that may provide reliable electrical signal paths between the controller 203 of the test system 200 and a device under test, such as an above-described in-progress MCM package 100. The socket 206 may include an open interior region or socket housing 204 defined by a socket housing plate 205 and one or more socket housing sidewalls 207. The socket 206 may be attached to a socket base 201 such that the socket housing plate 205 may be recessed relative to the socket base 201.

The socket housing plate 205 may include a plurality of openings 219. A plurality of contact pins 213 may extend through the openings 219 in the socket housing plate 205 into the socket housing 204. The contact pins 213 may include an electrically conductive material. In some embodiments, the contact pins 213 may be spring-loaded contact pins (e.g., pogo pins). Each of the contact pins 213 may be electrically coupled to a circuit board 215, which may also be referred to as a “load board. ” The load board 215 may be disposed on the test head 202 and the socket 206 may be located over the load board 215. The load board 215 may provide an electrical interface between the contact pins 213 and the controller 203 of the test system 200.

Referring again to FIG. 2A, the test system 200 may further include a contact blade 220. The contact blade 220 may include a chuck 221 and a die pusher 223. The die pusher 223 may include an upper portion 224 and a lower portion 225 that extends through an opening in the chuck 221. The lower portion 225 of the die pusher 223 may have a lower surface 217 that is configured to engage with an upper surface of a device under test (e.g., an above-described MCM package 100) that is located within the socket housing 204. In various embodiments, the lower surface 217 of the lower portion 225 of the die pusher 223 may have a non-planar surface, such as a curved and/or contoured surface. In the embodiment of FIG. 2A, the lower surface 217 has a concave curved surface. In other embodiments, described in further detail below, the lower surface 217 may have a convex curved surface. The lower surface 217 of the lower portion 225 of the die pusher 223 may also have at least one trench 218, as described in further detail below.

FIG. 2B is a vertical cross-section view of an in-progress MCM package 100 disposed in the test system 200 of FIG. 2A according to various embodiments of the present disclosure. Referring to FIG. 2B, a material handling system (not shown in FIG. 2B) may be utilized to place an above-described in-progress MCM package 100 into the socket housing 204 of the test system 200. The in-progress MCM package 100 may be placed into the socket housing 204 such that each bonding pad 111 on the second side 104 of the in-progress MCM package 100 may be aligned with a corresponding contact pin 213 of the socket 206. The contact blade 220 may be positioned over the socket 206 such that the die pusher 223 may be aligned over the plurality of dies 103a and 103b of the in-progress MCM package 100.

FIG. 2C is a vertical cross-section view of an in-progress MCM package 100 undergoing a testing process by the test system 200 of FIG. 2A according to various embodiments of the present disclosure. Referring to FIG. 2C, the controller 203 of the test system 200 may cause the contact blade 220 to move vertically downwards towards the socket 206 such that the lower surface 217 of the lower portion 225 of the die pusher 223 contacts the upper surface 110 of the in-progress MCM package 100 located in the socket housing 204. The contact blade 220 may apply a controlled downward pressure on the in-progress MCM package 100 that may cause the contact pins 213 of the socket 206 to engage with corresponding bonding pads 111 on the second surface 104 of the package substrate 101. In some embodiments, a lower portion of the chuck 221 may contact the upper surface 102 of the package substrate 101. In some embodiments, one or more mechanical stops 214, which may be located on the socket base 201, may prevent the contact blade 220 from exerting excessive pressure on the in-progress MCM package 100.

To perform a test on the in-progress MCM package 100, the controller 203 of the test system 200 may cause electrical test signals to be transmitted to the bonding pads 111 of the in-progress MCM package 100 via the load board 215 and the contact pins 213. Electrical response signals from the in-progress MCM package 100 may be received through the bonding pads 111, the contact pins 213 and the load board 215. The controller 203 may analyze the detected response signals from the in-progress MCM package 100 to determine whether the in-progress MCM package 100 includes any functional defects. Based on the testing, multiple in-progress MCM packages 100 may be sorted such that in-progress MCM packages 100 that are determined to not be defective may proceed to undergo additional package assembly processes while defective packages 100 may be segregated and optionally discarded.

Following the testing process, the contact blade 220 may be moved vertically away from the in-progress MCM package 100 and the in-progress MCM package 100 may be removed from the socket housing 204 by the material handling system.

In various embodiments, the shape of the lower surface 217 of the lower portion 225 of the die pusher 223 of the contact blade 220 may be complementary to the shape of the upper portion 110 of the in-progress MCM package 100 that is contacted by the die pusher 223 during the testing process. In the embodiment of FIGS. 2A-2C, for example, the concave shape of the lower surface 217 of the lower portion 225 of the die pusher 223 is complementary to the concave shape of the upper surface 110 of the in-progress MCM package 100 that is defined by the encapsulant material 109. In various embodiments, the shape of the lower surface 217 of the lower portion 225 of the die pusher 223 may correspond to the warpage characteristics of the in-progress MCM package 100. This may enable the contact blade 220 to apply pressure more evenly to the in-progress MCM package 100 which may help to prevent die cracking and other damage and improve test reliability.

Referring again to FIGS. 2A-2C, the location of the trench 218 in the lower surface 217 of the lower portion 225 of the die pusher 223 of the contact blade 220 may correspond to the location of the gap 106 between the adjacent ones of the plurality of dies 103a and 103b of the in-progress MCM package 100 in instances in which the die pusher 223 is brought into contact with the upper surface 110 of the in-progress MCM package 100. In some embodiments, during a testing process where the lower surface 217 of the lower portion 225 of the die pusher 223 contacts the upper surface 110 of the in-progress MCM package 100, the lower surface 217 may not contact the encapsulant material 209 located within and/or overlying the gap 106 between the adjacent dies 103a, 103b, 103c of the in-progress MCM package 100 due to the presence of the trench 218. In various embodiments, providing a trench 218 in the lower surface 217 of the lower portion 225 of the die pusher 223 may further minimize the risk of the contact blade 220 causing die cracking or other damage to the in-progress MCM package 100.

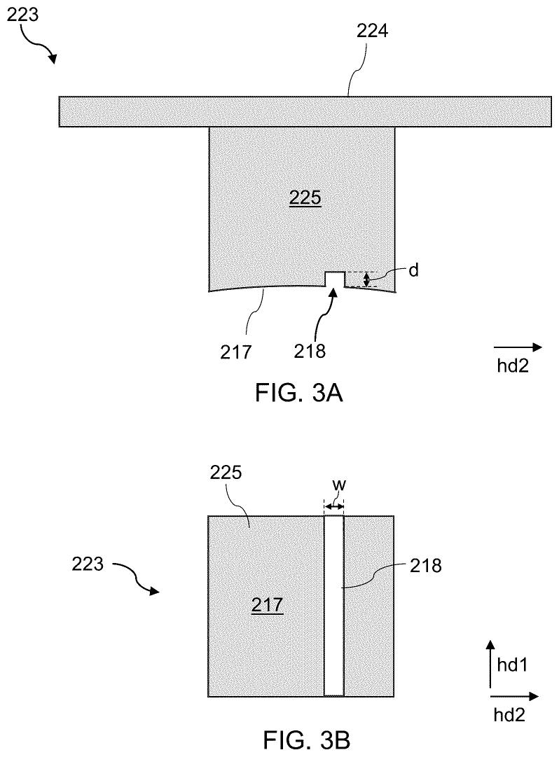

FIG. 3A is a vertical cross-section view of a die pusher 223 according to various embodiments of the present disclosure. FIG. 3B is a bottom view of the die pusher 223 shown in FIG. 3A. Referring to FIGS. 3A and 3B, the die pusher 223 may be utilized in a contact blade 220 of a test system 200 as described above with reference to FIGS. 2A-2C. In this embodiment, the lower surface 217 of the lower portion 225 of the die pusher 223 has a concave shape. FIGS. 3A and 3B also illustrate the trench 218 in the lower surface 217 of the lower portion 225 of the die pusher 223. Although FIGS. 3A and 3B illustrate a single trench 218, it will be understood that multiple trenches 218 may be located in the lower surface 217 of the lower portion 225 of the die pusher 223. Each trench 218 may correspond to the location of a gap 106 between adjacent ones of the plurality of dies 103a, 103b of the in-progress MCM package 100. Referring to FIG. 3A, a depth dimension, d, of each trench 218 may be at least about 5 μm, such as between about 5 μm and about 1 mm. Referring to FIG. 3B, a width dimension, w, of each trench 218 may be at least about 20 μm, such as between about 20 μm and about 1 mm. In the embodiment of FIGS. 3A and 3B, the trench 218 extends along the entire length of the lower surface 217 of the lower portion 225 of the die pusher 223 (i.e., between opposite sides of the lower surface 217 along a first horizontal direction hd1). In other embodiments, one or more trenches 218 may not extend along the entire length of the lower surface 217. Further, although FIGS. 3A and 3B illustrate a trench 218 extending along a first horizontal direction hd1, alternatively, or in addition, one or more trenches 218 may extend along a second horizontal direction hd2, along a diagonal direction, or in any pattern that may correspond to the location(s) of one or more gaps 106 between adjacent dies 103a, 103b of the in-progress MCM package 100.

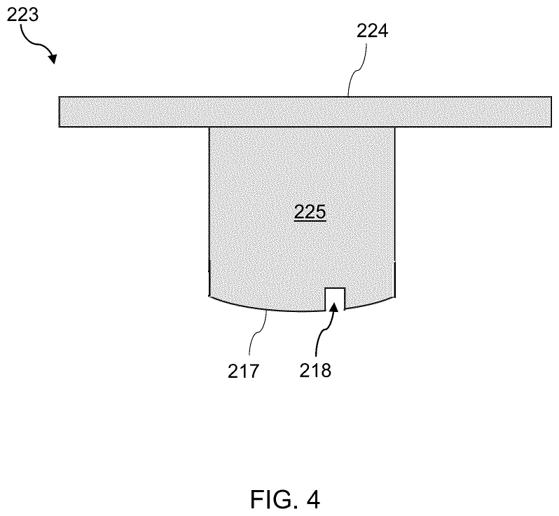

FIG. 4 is a vertical cross-section view of a die pusher 223 according to another embodiment of the present disclosure. Referring to FIG. 4, the lower surface 217 of the lower portion 225 of the die pusher 223 has a convex shape in this embodiment. A die pusher 223 as shown in FIG. 4 may be used, for example, in cases where the upper surface 110 of the in-progress MCM package 100 has a concave shape due to the warpage of the package substrate 101 causing the package substrate 101 to “bow” upwards towards the periphery of the package substrate 101. The convex shape of the lower surface 217 of the lower portion 225 of the die pusher 223 may complement the concave shape of the upper surface 110 of the in-progress MCM package 100 that is contacted by the die pusher 223 during the testing process. This may enable the contact blade 220 to apply pressure more evenly to the in-progress MCM package 100 which may help to prevent die cracking and other damage and improve test reliability. The die pusher 223 in the embodiment of FIG. 4 additionally includes a trench 218 in the lower surface 217 of the lower portion 225 of the die pusher 223, which may be similar or identical to the trench 218 described above with reference to FIGS. 3A and 3B.

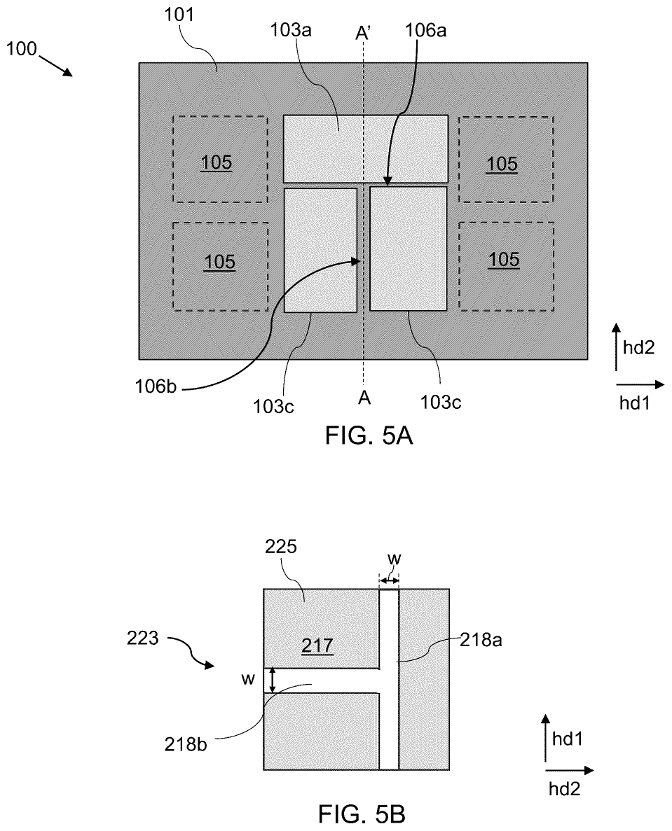

FIG. 5A is a top view of an alternative in-progress multi-chip module (MCM) package 100 according to an alternative embodiment of the present disclosure. The MCM package 100 is similar to the MCM package of FIG. 1A and thus, discussion of similar features is omitted for brevity. FIG. 5B is a bottom view of an alternative die pusher shown used in conjunction with the alternative MCM package of FIG. 5A. the bottom view in FIG. 5B is similar to the bottom view in FIG. 3B. Thus, discussion of similar features is omitted for brevity.

Referring to FIG. 5A, the in-progress MCM package 100 may include a plurality of dies 103a and 103b may be mounted over the first side 102 of the package substrate 101. Although FIGS. 1A and 1B illustrate a first die 103a and a plurality of dies 103b mounted to the package substrate 101, it will be understood that a greater or lesser number of dies may be mounted to the package substrate 101. Each of the dies 103a and 103c may include any suitable die, such as a logic die (e.g., a CPU die, a GPU die, an ASIC die, etc.), a memory die (e.g., an SRAM die, an HBM die, etc.), an analog die, an RF die, an integrated passive device (IPD) die, a deep trench capacitor (DTC) die, a non-functional “dummy” die, etc., including various combinations thereof.

The plurality of dies 103a and 103c may be bonded to the package substrate 101 using any suitable bonding technique, such as a microbump bonding technique, a direct bond (e.g., a metal-to-metal and dielectric-to-dielectric) bonding technique, a flip chip bonding technique, etc., including various combinations thereof. In some embodiments, the plurality of dies 103a and 103c may be directly attached to the first side 102 of the package substrate 101. Alternatively, or in addition, one or more of the plurality of dies 103a and 103c may be attached to an intervening structure, such as an interposer, that may be mounted to the first side 102 of the package substrate 101. The interposer may electrically couple the plurality of dies 103a and 103c to the package substrate 101. Each of the plurality of dies 103a and 103c may be laterally spaced from one another such that there is a gap 106a located between adjacent ones of the plurality of dies 103a and 103c. In addition, each of the plurality of dies 103a and 103c may be laterally spaced from one another such that there is a gap 106b located between adjacent ones of the plurality of dies 103c.

Referring to FIG. 5B, the die pusher 223 may be utilized in a contact blade 220 of a test system 200 as described above with reference to FIGS. 2A-2C. FIG. 5B illustrates a trench 218a and a second trench 218b in the lower surface 217 of the lower portion 225 of the die pusher 223. Each trench 218a and 218b may correspond to the respective location of a gap 106a and gap 106b between adjacent ones of the plurality of dies 103a, 103c of the in-progress MCM package 100. Similar to the trench in FIG. 3A, a depth dimension, d, of each trench 218a and trench 218b may be at least about 5 μm, such as between about 5 μm and about 1 mm. Referring to FIG. 5B, a width dimension, w, of each trench 218a and trench 218b may be at least about 20 μm, such as between about 20 μm and about 1 mm. In the embodiment of FIG. 5B, the trench 218a extends along the entire length of the lower surface 217 of the lower portion 225 of the die pusher 223 (i.e., between opposite sides of the lower surface 217 along a first horizontal direction hd1). In addition, trench 218b extends from one side of the lower surface 217 of the lower portion 225 to the trench 218a along a second horizontal direction hd2. Alternatively, or in addition, one or more trenches 218 may extend along a second horizontal direction hd2, along a diagonal direction, or in any pattern that may correspond to the location(s) of one or more gaps 106 between adjacent dies 103a, 103b, 103c of the in-progress MCM package 100.

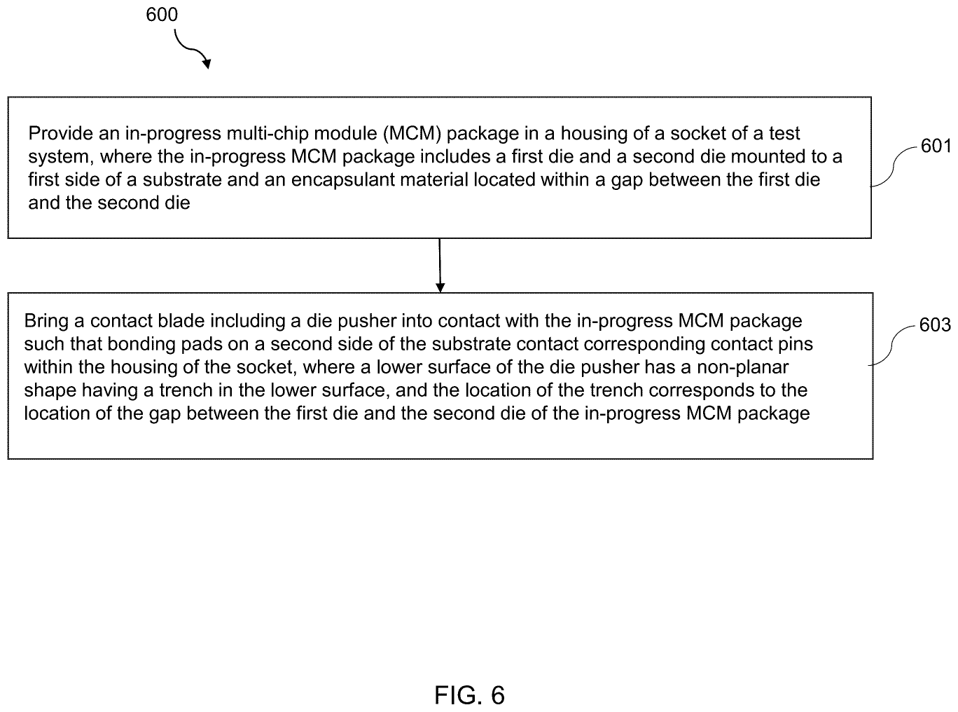

FIG. 6 is a flow chart showing a method 600 of testing an in-progress MCM package 100 according to various embodiments of the present disclosure. Referring to FIGS. 1A-2B and 6, in step 601 of method 600, an in-progress multi-chip module (MCM) package 100 may be provided in a housing 204 of a socket 206 of a test system 200, where the in-progress MCM package 100 includes a first die 103a and a second die 103b or 103c mounted to a first side 102 of a substrate 101 and an encapsulant material 109 located within a gap 106 between the first die 103a and the second die 103b or 103c. Referring to FIGS. 2C-6, in step 603 of method 600, a contact blade 220 including a die pusher 223 may be brought into contact with the in-progress MCM package 100 such that bonding pads 111 on a second side 104 of the substrate 101 contact corresponding contact pins 213 within the housing 204 of the socket 206, where a lower surface 217 of the die pusher 223 has a non-planar shape having a trench 218 in the lower surface 217, and the location of the trench 218 corresponds to the location of the gap 106 between the first die 103a and the second die 103b or 103c of the in-progress MCM package 100.

Referring to all drawings and according to various embodiments of the present disclosure, a test system 200 for testing semiconductor package structures includes a socket 206 including a socket housing plate 205 having a plurality of openings 219, and a plurality of contact pins 213 extending through the openings 219 into a housing 204 of the socket 206, and a contact blade 220 including a die pusher 223 having a lower surface 217 configured to contact an upper surface 110 of a semiconductor package structure 100 located in the socket 206, where the lower surface 217 of the die pusher 223 includes a non-planar shape.

In one embodiment, the semiconductor package structure includes an in-progress multi-chip module (MCM) package 100 having a first die 103a and a second die 103b mounted to a substrate 101, where the lower surface 217 of the die pusher 223 includes a trench 218 located therein, and a location of the trench 218 in the lower surface 218 of the die pusher 223 corresponds to a location of a gap 106 between the first die 103a and the second die 103b when the die pusher 223 is brought into contact with the upper surface 110 of the in-progress MCM package 100 disposed in the housing 204 of the socket 206. In another embodiment, the first die 103a and the second die 103b are mounted to a first side 102 of the substrate 101 of the in-progress MCM package 100, a second side 104 of the in-progress MCM package 100 includes a plurality of bonding pads 111, and the die pusher 223 is configured to apply pressure to the upper surface 110 of the in-progress MCM package 100 such that each of the bonding pads 111 on the second side 104 of the substrate 101 electrically contacts a corresponding contact pin 213 of the plurality of contact pins 213 extending into the housing 204 of the socket 206. In another embodiment, the contact blade 220 further includes a chuck 221, the die pusher 223 is attached to the chuck 221, and a lower portion of the chuck 221 is configured to contact the first side 102 of the substrate 101 of the in-progress MCM package 100. In another embodiment, the lower surface 217 of the die pusher 223 includes a plurality of trenches 218, wherein a location of each trench 218 in the lower surface 217 of the die pusher 223 corresponds to a location of a gap 106 between adjacent dies 103a, 103b of an in-progress MCM package 100 when the die pusher 223 is brought into contact with the upper surface 110 of the in-progress MCM package 100 disposed in the housing 204 of the socket 206.

In another embodiment, the lower surface 217 of the die pusher 223 has a concave shape. In another embodiment, the lower surface 217 of the die pusher 223 has a convex shape. In another embodiment, the test system 200 further includes a circuit board 215, the socket 206 disposed on the circuit board 215, where the contact pins 213 include pogo pins and are electrically coupled to the circuit board 215. In another embodiment, the trench 218 in the lower surface 217 of the die pusher 223 has depth dimension d of at least 5 μm and a width dimension w of at least 20 μm.

Another embodiment is drawn to a die pusher 223 for a test system 200 for testing semiconductor package structures that includes a lower surface 217 configured to contact and apply pressure to a surface 110 of a semiconductor package structure 100, and a trench 218 in the lower surface 217 of the die pusher 223.

In one embodiment, the lower surface 217 of the die pusher 223 has a non-planar contoured surface. In another embodiment, the lower surface 217 of the die pusher 223 has a concave surface. In another embodiment, the lower surface 217 of the die pusher 223 has a convex surface. In another embodiment, the trench 218 has a depth dimension d that is at least 5 μm and less than or equal to 1 mm. In another embodiment, the trench 218 has a width dimension w that is at least 20 μm and less than or equal to 1 mm. In another embodiment, the lower surface 217 of the die pusher 223 includes a plurality of trenches 218.

Another embodiment is drawn to a method of testing a semiconductor package 100 that includes providing a multi-chip module (MCM) package 100 in a housing 204 of a socket 206 of a test system 200, where the MCM package 100 includes a first die 103a and a second die 103b mounted to a first side 102 of a substrate 101 and an encapsulant material 109 located within a gap 106 between the first die 103a and the second die 103b, and bringing a contact blade 220 including a die pusher 223 into contact with the MCM package 100 such that bonding pads 111 on a second side 104 of the substrate 101 contact corresponding contact pins 213 within the housing 204 of the socket 206, where a lower surface 217 of the die pusher 223 includes a non-planar shape.

In one embodiment, the encapsulant material 109 forms a non-planar upper surface 110 of the in-progress MCM package 100, and wherein bringing the contact blade 223 into contact with the in-progress MCM package 100 includes contacting the lower surface 217 of the die pusher 223 against the non-planar upper surface 110 of the in-progress MCM package 100, the lower surface of the die pusher includes a trench 218, and a location of the trench 218 corresponds to a location of the gap 106 between the first die 103a and the second die 103b of the MCM package 100.

In another embodiment, a shape of the lower surface 217 of the die pusher 223 is complementary to the shape of the upper surface 110 of the MCM package 100. In another embodiment, the shape of the upper surface 110 of the MCM package 100 is convex and the shape of the lower surface 217 of the die pusher 223 is concave.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A test system for testing semiconductor package structures, comprising:
a socket, comprising:
a socket housing plate comprising a plurality of openings; and
a plurality of contact pins extending through the openings into a housing of the socket; and
a contact blade comprising a die pusher having a lower surface configured to contact an upper surface of a semiconductor package structure located in the socket, wherein the lower surface of the die pusher comprises a non-planar shape.

2. The test system of claim 1, wherein the semiconductor package structure comprises an in-progress multi-chip module (MCM) package comprising a first die and a second die mounted to a substrate, wherein the lower surface of the die pusher comprises a trench located therein., and a location of the trench in the lower surface of the die pusher corresponds to a location of a gap between the first die and the second die when the die pusher is brought into contact with the upper surface of the in-progress MCM package disposed in the housing of the socket.

3. The test system of claim 2, wherein the first die and the second die are mounted to a first side of the substrate of the in-progress MCM package, a second side of the in-progress MCM package comprises a plurality of bonding pads, and the die pusher is configured to apply pressure to the upper surface of the in-progress MCM package such that each of the bonding pads on the second side of the substrate electrically contacts a corresponding contact pin of the plurality of contact pins extending into the housing of the socket.

4. The test system of claim 2, wherein the contact blade further comprises a chuck, the die pusher is attached to the chuck, and a lower portion of the chuck is configured to contact the first side of the substrate of the in-progress MCM package.

5. The test system of claim 2, wherein the lower surface of the die pusher comprises a plurality of trenches, wherein a location of each trench in the lower surface of the die pusher corresponds to a location of a gap between adjacent dies of an in-progress MCM package when the die pusher is brought into contact with the upper surface of the in-progress MCM package disposed in the housing of the socket.

6. The test system of claim 1, wherein the lower surface of the die pusher has a concave shape.

7. The test system of claim 1 wherein the lower surface of the die pusher has a convex shape.

8. The test system of claim 1, further comprising:
a circuit board, the socket disposed on the circuit board, wherein each of the plurality of contact pins comprise pogo pins and are electrically coupled to the circuit board.

9. The test system of claim 1, wherein the trench in the lower surface of the die pusher has depth dimension of at least 5 μm and a width dimension of at least 20 μm.

10. A die pusher for a test system for testing semiconductor package structures, comprising:
a lower surface configured to contact and apply pressure to a surface of a semiconductor package structure; and
a trench in the lower surface of the die pusher.

11. The die pusher of claim 10, wherein the lower surface of the die pusher comprises a non-planar contoured surface.

12. The die pusher of claim 11, wherein the lower surface of the die pusher comprises a concave surface.

13. The die pusher of claim 11, wherein the lower surface of the die pusher comprises a convex surface.

14. The die pusher of claim 10, wherein the trench has a depth dimension that is at least 5 μm and less than or equal to 1 mm.

15. The die pusher of claim 10, wherein the trench has a width dimension that is at least 20 μm and less than or equal to 1 mm.

16. The die pusher of claim 10, wherein the lower surface of the die pusher comprises a plurality of trenches.

17. A method of testing a semiconductor package, comprising:
providing a multi-chip module (MCM) package in a housing of a socket of a test system, wherein the MCM package comprises a first die and a second die mounted to a first side of a substrate and an encapsulant material located within a gap between the first die and the second die; and
bringing a contact blade comprising a die pusher into contact with the MCM package such that bonding pads on a second side of the substrate contact corresponding contact pins within the housing of the socket, wherein a lower surface of the die pusher comprises a non-planar shape.

18. The method of claim 17, wherein the encapsulant material forms a non-planar upper surface of the MCM package, and wherein bringing the contact blade into contact with the MCM package comprises contacting the lower surface of the die pusher against the non-planar upper surface of the MCM package, the lower surface of the die pusher comprises a trench, and a location of the trench corresponds to a location of the gap between the first die and the second die of the MCM package.

19. The method of claim 18, wherein a shape of the lower surface of the die pusher is complementary to the shape of the upper surface of the MCM package.

20. The method of claim 19, wherein the shape of the upper surface of the MCM package is convex and the shape of the lower surface of the die pusher is concave.
